(19) United States
(12) Patent Application Publication
(10) Pub. No.: US 2023/0100613 A1
(43) Pub. Date: Mar. 30, 2023

(54) WAFER CHUCK FOR A LASER BEAM WAFER DICING EQUIPMENT

(71) Applicant: Infineon Technologies AG, Neubiberg (DE)

(72) Inventors: Franz-Josef Pichler, Villach (AT); Johannes Mueller, Villach (AT); Christoph Ahamer, Villach (AT); Gerald Lackner, Arnoldstein (AT); Walter Horst Leitgeb, Wernberg (AT)

(21) Appl. No.: 17/942,487

(22) Filed: Sep. 12, 2022

(30) Foreign Application Priority Data
Sep. 24, 2021 (DE) 102021124738.1

(51) Int. Cl. H01L 21/683; H01L 21/67; H01L 21/268; H01L 21/78

(52) U.S. Cl. CPC H01L 21/6838; H01L 21/67092; H01L 21/67115; H01L 21/6836; H01L 21/268; H01L 21/78; H01L 2221/68327; H01L 29/1608

(57) ABSTRACT

A chuck for a laser beam wafer dicing equipment includes a wafer support plate having an upper surface for holding a wafer disposed on a dicing tape. The upper surface includes an annular groove that overlaps an edge of the wafer when the wafer disposed on the dicing tape is placed on the upper surface. The wafer support plate includes a ventilation channel configured to ventilate the annular groove.

### TECHNICAL FIELD

The disclosure relates the field of wafer handling, and in particular to a wafer chuck and a method for laser beam wafer dicing.

### BACKGROUND

One specific process in wafer handling includes mounting a wafer on a dicing tape and separating the wafer into dies by using a laser beam wafer dicing equipment. More specifically, the wafer mounted on the dicing tape is placed on an upper surface of a wafer support plate of a wafer chuck, and a laser beam is used to cut the wafer into dies when passed over the wafer.

A problem is that the dicing tape holding the wafer during the cutting process (die separation) may stick to the wafer support plate of the wafer chuck in the area outside the wafer edge (i.e. where the laser beam directly hits the tape). This may cause chuck contamination by tape residues sticking to the wafer support plate of the chuck and further difficulties, namely die-knocking, i.e. the already cut dies hit each other when the tape is lifted off with the cut wafer on it, or the tape sticks so strongly to the chuck that it cannot be lifted off at all. The process of chuck contamination is self-intensifying, and in addition, the upper surface of the chuck may be directly damaged by the laser beam in the overcut area.

Conventionally, chemical cleaning and high temperature cleaning of the chuck is used to remove the tape residues from the support plate of the chuck. This is usually performed about once a day and is quite costly.

Another way to avoid the difficulties is to use a dicing tape that is specifically suited to laser dicing. This is extremely demanding, as subsequent processes must be precisely matched to the new dicing tape. Thus, if a different dicing tape were used, many subsequent processes would have to be changed.

A third possibility is to stop the laser beam before reaching the wafer edge and to perform breaking of the wafer in the area of the wafer edge in the backend (BE), where the dicing tape is expanded. However, this is also not feasible from a practical point of view, since breaking the wafer edge in the BE generates particle contamination that is not acceptable at that stage of the procedure (e.g. during a BE pick and place process).

### SUMMARY

According to an aspect of the disclosure a chuck for a laser beam wafer dicing equipment includes a wafer support plate having an upper surface for holding a wafer disposed on a dicing tape. The upper surface includes an annular groove that overlaps the wafer edge when the wafer disposed on the dicing tape is placed on the upper surface. The wafer support plate includes a ventilation channel configured to ventilate the annular groove.

According to another aspect of the disclosure a laser beam wafer dicing equipment includes a chuck as described above. The laser beam wafer dicing equipment further includes a laser unit for producing a laser beam configured to cut the wafer into dies when passed over the wafer.

According to another aspect of the disclosure a method of dicing a wafer includes placing a wafer on an upper surface of a wafer support plate of a chuck. A dicing tape is disposed between the upper surface and the wafer. The upper surface includes an annular groove that overlaps the wafer edge. The annular groove is ventilated. The wafer is cut into dies by passing a laser beam over the wafer. The dicing tape is lifted together with the dies off the upper surface.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other and/or can be selectively omitted if not described to be necessarily required. Embodiments are depicted in the drawings and are exemplarily detailed in the description which follows.

FIG. 1 is a schematic cross-sectional view of an example of a laser beam wafer dicing equipment.

FIG. 2 is a schematic cross-sectional partial view of an exemplary wafer support plate of a chuck, the wafer support plate having a non-vented annular groove in the vicinity of the wafer edge.

FIG. 3 is a schematic cross-sectional partial view of an exemplary wafer support plate of a chuck, the wafer support plate having a vented annular groove of large width in the vicinity of the wafer edge.

FIG. 4 is a schematic cross-sectional partial view of an exemplary wafer support plate of a chuck, the wafer support plate having a vented annular groove of a suitable width in the vicinity of the wafer edge.

FIG. 5 is a schematic cross-sectional partial view of an exemplary wafer support plate of a chuck, the wafer support plate having a vented annular groove in the vicinity of the wafer edge and a vacuum system comprises vacuum suction grooves and/or vacuum suction holes.

FIG. 6 is a perspective cut-away partial view of a wafer chuck having a base plate arranged below and spaced apart from the wafer support plate.

FIG. 7 is a perspective top view of an exemplary wafer support plate of a wafer chuck.

FIG. 8 is a flowchart illustrating an exemplary method of dicing a wafer.

### DETAILED DESCRIPTION

As used in this specification, layers or elements illustrated as adjacent layers or elements do not necessarily be directly contacted together; intervening elements or layers may be provided between such layers or elements. However, in accordance with the disclosure, elements or layers illustrated as adjacent layers or elements may in particular be directly contacted together, i.e. no intervening elements or layers are provided between these layers or elements, respectively.

The words “over” or “beneath” with regard to a part, element or material layer formed or located or disposed or arranged or placed “over” or “beneath” a surface may be used herein to mean that the part, element or material layer be located (e.g. placed, formed, arranged, disposed, placed, etc.) “directly on” or “directly under”, e.g. in direct contact with, the implied surface. The word “over” or “beneath” used with regard to a part, element or material layer formed or located or disposed or arranged or placed “over” or “beneath” a surface may, however, either be used herein to mean that the part, element or material layer be located (e.g. placed, formed, arranged, deposited, etc.) “indirectly on” or “indirectly under” the implied surface, with one or more additional parts, elements or layers being arranged between the implied surface and the part, element or material layer.

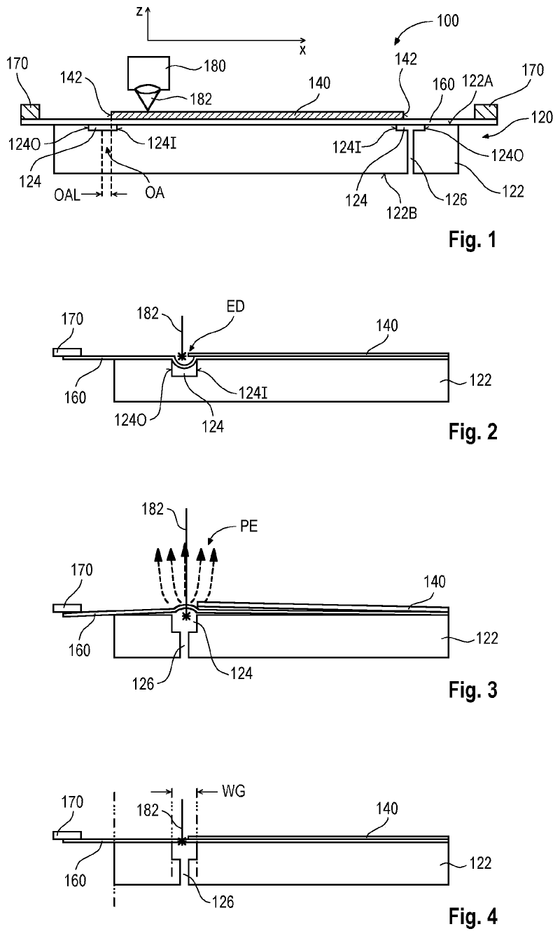

Referring to FIG. 1, a laser beam wafer dicing equipment 100, in the following referred to as wafer dicing equipment 100, may include a chuck 120 and a laser unit 180 for producing a laser beam 182.

As known in the art, chucks 120 are devices configured to support wafers during various stages of wafer processing. Usually, chucks are designed according to the wafer processing performed on the wafer while the wafer is being held by the chuck. In the following, a chuck 120 is considered which is designed to support a wafer during laser beam wafer dicing. Such chuck 120 is also referred to as a “dicing chuck” in the art.

FIG. 1 illustrates a part of such wafer dicing equipment 100, namely the chuck 120 and the laser unit 180. The wafer dicing equipment 100 may further comprise a mechanism (not shown) for carrying the chuck 120 and a mechanism (not shown) to which the laser unit 180 is mounted. These mechanisms allow to move the laser unit 180 relative to the chuck 120 in a lateral direction (X and/or Y-directions) and in the Z-direction (i.e. in a direction perpendicular to the plane defined by the X-direction and the Y-direction, with the Y-direction being perpendicular to the paper plane).

The chuck 120 includes a wafer support plate 122 having an upper surface 122A and a lower surface 122B opposite the upper surface 122A. Typically, the chuck 120 comprises additional plates (e.g. a chuck basement plate and/or a chuck vacuum plate and/or a chuck receptacle) arranged beneath the wafer support plate 122. Such plates, which provide mechanical stability and/or vacuum functionality to the chuck 120, are not shown in FIG. 1. In other words, FIG. 1 only illustrates the top plate of the chuck 120, namely the wafer support plate 122.

The wafer support plate 122 may, e.g., comprise or be made of glass, e.g. quartz glass, or other material(s) such as, e.g., a metal material (e.g. stainless steel) or polycarbonate.

During operation of the wafer dicing equipment 100, a wafer 140 is placed on and held by the upper surface 122A of the wafer support plate 122. The wafer 140 is mounted on a dicing tape 160. That is, the dicing tape 160 has a lower surface which may directly contact the upper surface 122A of the wafer support plate 122, and as has an upper surface which may directly contact and stick to the lower surface of the wafer 140. That is, the dicing tape 160 is disposed between the upper surface 122A of the wafer support plate 122 and the wafer 140.

The dicing tape 160 may be affixed to a dicing frame 170. The dicing frame 170 is used as a transport and mounting tool of the dicing tape 160 with the wafer 140 mounted thereon. During the process of dicing the wafer 140, the dicing frame 170 may be fixed by releasable connection means (e.g. clamps or screw connections or vacuum cups (not shown)) to the chuck 120. That is, the wafer support plate 122 and the dicing tape 160 are in a fixed positional relationship during operation of the wafer dicing equipment 100.

The dicing tape 160 is needed to support each die after die separation (i.e. after cutting the wafer 140 into a plurality of dies by passing the laser beam 182 over the wafer 140). After die separation, the dicing tape 160 is lifted together with the dies off the upper surface 122A of the wafer support plate 122. Lifting the dicing tape 160 together with the dies off the upper surface 122A may be done by a mechanism (not shown) which provides for a relative movement between the wafer support plate 122 and the dicing frame 170 in Z-direction.

The laser unit 180 may be of any kind suitable for laser dicing. In particular, a UV (ultraviolet) laser or a green laser (e.g. 532 nm wavelength) or an IR (infrared) laser may be used which is, e.g., efficient for separating of wafers 140 which require high energy for laser dicing. Further, a pulse laser may be used for separation.

The wafer 140 may be of any semiconductor material such as, e.g., SiC, Si, GaN, etc. The wafer 140 may have a thickness of equal to or greater than 20 μm or 50 μm or 100 μm. Depending on the semiconductor material and the wafer thickness, the laser energy and/or pulse length has to be chosen appropriately.

For example, SiC is a very mechanical resistant and electrical efficient material. The mechanical properties of SiC are comparable to diamond. Further, in the backend (BE) process, SiC dies are very sensitive, and this needs to be considered already at the stage of wafer separation.

To arrive at high yields, the dicing process needs to be adjusted to the thickness to the wafer and has to ensure a full separation and overcut on the wafer edge in order to guarantee complete wafer separation. In this overcut area OA (see FIG. 1), the full laser energy of the semiconductor dicing process is introduced into the dicing tape 160.

As a result, the dicing tape 160 can be modified or damaged by local melting on its upper side, backside and within the tape (e.g. at intermediate layers, if provided).

Further consequences of the laser beam 182 surpassing the wafer edge 142 are that the upper surface 122A of the wafer support plate 122 can be locally damaged (chip-outs) and/or that locally melted dicing tape 160 can stick to the upper surface 122A of the wafer support plate 122. The latter effect causes a contamination of the dicing chuck 120. Both effects, i.e. damage and contamination of the upper surface 122A of the wafer support plate 122, are self-intensifying, i.e. pre-damaged and/or pre-contaminated surface areas are more prone to further damage or contamination than intact surface areas.

As a result, the automated wafer lift-off from the wafer support plate 122 may become more difficult or may not work after a relatively small number of processed wafers 140. The contamination and damages (e.g. cut lines) at the upper surface 122A of the wafer support plate 122 will increase wafer per wafer. At the end, the sticky wafer 140 needs to be removed manually from the chuck 120. This can lead to wafer scrap. As a worst-case scenario from a product reliability point of view, the wafer lift-off (so-called de-chucking) is still possible, but a locally sticking dicing tape 160 may lead to bending of the dicing tape 160. As a result, die knocking can occur and may induce cracks and chipping at the dies.

For example, the above problems are severe when cutting a SiC wafer of a thickness of equal to or greater than 100 μm.

To avoid these and other problems, the upper surface 122A of the wafer support plate 122 includes an annular groove 124 that overlaps the wafer edge 142 when the wafer 140 disposed on the dicing tape 160 is placed on the upper surface 122A.

The annular groove 124 partly or completely overlaps the wafer edge 142 when the wafer 140, mounted on the dicing tape 160, is placed on the upper surface 122A. For example, the entire wafer edge 142 may project radially beyond an inner edge 124I of the annular groove 124 but not beyond an outer edge 124O of the annular groove 124.

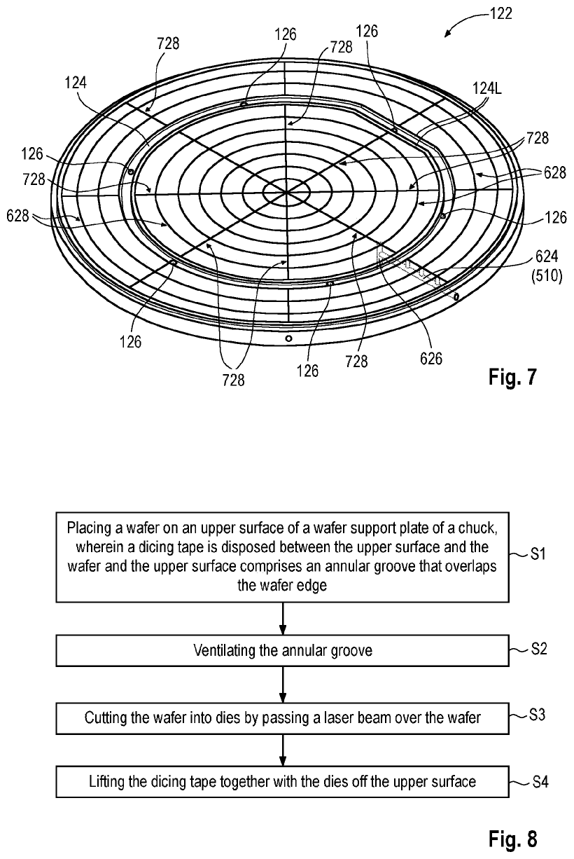

The annular groove 124 may be shaped as a ring. The inner edge 124I and/or the outer edge 124O may, e.g., be circular or part-circular (see e.g. FIG. 7).

The annular groove 124 may ensure that any contact between the upper surface 122A and the dicing tape 160 near the wafer edge 142 (i.e. within the overcut area OA) is avoided.

In other words, when cutting the wafer 140 into dies, a wafer edge overcut is applied. The overcut area length OAL is the radial dimension of the overcut area OA, see FIG. 1. The outer edge 124O of the annular groove 124 extends radially beyond the wafer edge 142 by at least the maximum overcut area length OAL.

The overcut area OA begins at the wafer edge 142. Its length OAL in the radial direction is defined by parameters such as the die size, wafer placement tolerances etc. Hence, different OALs may be used for different wafers. The annular groove 124 may be dimensioned to completely overlap the overcut area OA for all OALs (and hence, e.g., for all die sizes intended to be produced on the chuck 120), ensuring that wherever the (focused) laser beam 182 hits the dicing tape 160, the dicing tape 160 extends freely across the annular groove 124, i.e. is completely unsupported.

The overcut area length OAL may be set to 1.5 mm or less. For example, OAL may be equal to or greater than or less than 0.3 mm or 0.6 mm or 0.9 mm or 1.2 mm or 1.5 mm.

The avoidance of contact between the dicing tape 160 and the upper surface 122A of the wafer support plate 122 at and radially beyond the wafer edge 142 (e.g., at least in the overcut area OA) significantly reduces chuck contamination and therefore allows for a significant extension of the chuck cleaning time interval.

Further, the wafer support plate 122 comprises a ventilation channel 126 configured to ventilate the annular groove 124.

FIG. 2 illustrates a deformation of the dicing tape 160 in downward direction if vacuum is applied to the annular groove 124. In this case, the annular groove 124 would lead to wafer edge delamination ED of the dicing tape 160. Further, after wafer dicing, flying dies may be produced in the area where the wafer 140 extends over the inner edge 124I of the annular groove 124. To avoid dicing tape deformation in downward direction at the wafer edge 142 and thus edge delamination ED, a ventilation channel 126 is used (FIG. 3). The ventilation channel 126 communicates with the annular groove 124 and ensures that the annular groove 124 is vented to ambient pressure, e.g. atmospheric pressure. That way, the downward deformation of the dicing tape 160 occurring if the annular groove 124 is unvented and/or connected to the vacuum system can be avoided. As a result, delamination of the dicing tape 160 prior to the laser dicing process can be avoided.

FIG. 3 illustrates another problem which may arise even in the presence of a vented annular groove 124. The process exhaust PE generated by the laser beam 182 may lift the dicing tape 160 off the wafer support plate 122. This lifting of the dicing tape 160 can also be critical because at the time of cutting the wafer edge 142, the wafer 140 can no longer stabilize the dicing tape 160 at the wafer edge 142. As a result, also this effect may cause die knocking or even flying dies and, therefore, cannot be tolerated during wafer dicing.

It has been found that the area of the non-vacuum supported tape should be as small as possible to avoid the upward deformation effect of the dicing tape 160 shown in FIG. 3. Hence, the width of the annular groove 124 may be limited.

Further, a deformation of the dicing tape 160 as shown in FIG. 2 or 3 may cause the wafer edge 142 to move out of the focus of the laser beam 182. This may lead to not or not completely separated wafer edge regions due to the defocused laser beam 182. Also for this reason, the two effects (FIG. 2 and FIG. 3) need to be controlled.

It is to be noted that the adverse effects caused by tape downward deformation (FIG. 2) and tape upward deformation (FIG. 3) are only occurring during laser dicing, i.e. when the wafer edge 142 is diced so that the individual dies loose integrity and can contact each other.

FIG. 4 illustrates laser dicing operation in which a vented annular groove 124 is used and the width WG of the annular groove is set so as to avoid that the vacuum-unsupported area of the dicing tape 160 is too large. Preferably, the annular groove 124 may have a width WG between 1 and 8 mm, in particular between 5 and 7 mm. More specifically, the width WG of the annular groove may be equal to or greater than or less than 2 mm or 3 mm or 4 mm or 5 mm or 6 mm or 7 mm. The smaller the width WG of the annular groove 124 the smaller the area of the non-vacuum supported tape can be.

The annular groove 124 may have a depth between, e.g., 0.1 mm and 5 mm. In particular, the depth may be equal to or greater than or less than 0.5 mm or 1.0 mm or 2.0 mm or 3.0 mm or 4.0 mm or 5.0 mm.

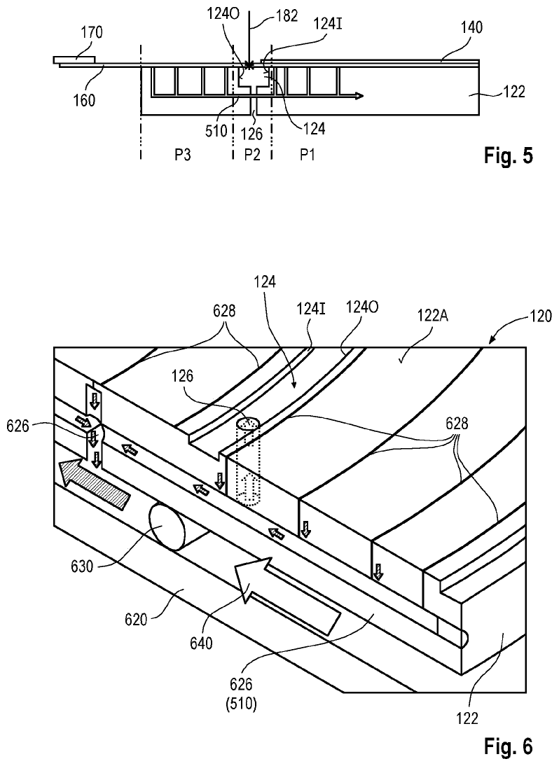

The non-vacuum supported tape area is equal to the width WG of the annular groove plus the distances from the inner and outer edges 124I, 124O of the annular groove 124 to the next vacuum suction groove or hole, respectively (see FIGS. 5 and 6). It is preferred that these distances are short, e.g. equal to or shorter than 4 mm or 3 mm or 2 mm or 1 mm. Further, the upper surface 122A of the wafer support plate 122 may have a small roughness and/or or a high flatness at least in the vicinity of the annular groove 124 to improve the mechanical contact between the wafer support plate 122 and the dicing tape 160 in the vicinity of the inner and outer edges 124I, 124O of the annular groove 124.

Referring to FIG. 5, the wafer support plate 122 includes a vacuum system which is configured to hold the dicing tape 160 to the upper surface 122A of the wafer support plate 122 by suction. More specifically, the vacuum system may comprise a first pressure region P1 which is located radially inward of the annular groove 124, a second pressure region P2 which includes the annular groove 124 and the ventilation channel 126, and a third pressure region P3 which is located radially outward of the annular groove 124.

The first pressure region P1 is pressurized by vacuum for wafer suction, the second pressure region P2 is vented (e.g. at atmospheric pressure) and the third pressure region P3 is pressurized by vacuum for dicing tape suction.

The pressure of the first and third pressure regions P1 and P3 may be different or may be equal. For example, the pressure regions P1 and P3 may be connected to each other by a pressure connection 510. The pressure connection 510 bridges the annular groove 124. The pressure connection 510 may be formed as a channel or duct extending in the interior of the wafer support plate 122.

FIG. 6 illustrates a cut-away partial view of a wafer chuck 120. The wafer chuck 120 includes a base plate 620 and the wafer support plate 122. The base plate 620 is arranged below and spaced apart from the wafer support plate 122.

In this and in all other examples, the upper surface 122A of the wafer support plate 122 may be equipped with thin vacuum suction grooves 628 arranged radially inside and radially outside the annular groove 124. Alternatively or in addition, vacuum suction holes (not shown) may be formed in the upper surface 122A of the wafer support plate 122. The vacuum suction grooves 628 and/or vacuum suction holes (not shown) form part of the pressure regions P1 and P3, respectively.

To this end, the wafer support plate 122 may, e.g., be provided with a vacuum duct 624 extending in the horizontal, e.g. radial direction. The vacuum duct 624 corresponds to the pressure connection 510 shown in FIG. 5. The vacuum duct 624 may connect the vacuum suction grooves 628 that are provided radially inward the annular groove 124 with the vacuum suction grooves 628 that are provided radially outward the annular groove 124.

The chuck 120 may further comprise an annular sealing 630 disposed between the base plate 620 and the wafer support plate 122. The annular sealing 630 may, e.g., be an O-ring or any other sealing means. The annular sealing 630 may seal an inner vacuum region between the base plate 630 and the wafer support plate 122 against an outer vented region between the base plate 620 and the wafer support plate 122. The ventilation air flow is indicated by an arrow at reference sign 640, internal vacuum gas flows (suction flows) are indicated by hatched arrows.

The inner vacuum region may be a part of the pressure regions P1 and P3. The outer vented region may be a part of the pressure region P2.

More specifically, the vacuum supply for the pressure region P3 outside of the annular groove 124 may be implemented by a horizontal pressure connection 510 (e.g. vacuum duct 624) which traverses below the annular groove 124 to the inner vacuum region. The connection between the inner vacuum region (between the base plate 620 and the wafer support plate 122) and the horizontal pressure connection 510 may be formed by one or a plurality of connecting holes 626. The ventilation channel 126 of the wafer support plate 122 may pass through the wafer support plate 122 and be in communication with the outer vented region. Here and in all examples disclosed herein, the ventilation channel 126 may have a diameter of e.g. equal to or greater than or less than 2 mm or 3 mm or 4 mm.

The design of the vacuum suction grooves 628 should be adapted to the exhaust adjustment as described in conjunction with FIG. 3. More specifically, the vacuum suction grooves 628 neighboring the annular groove 124 should be located as close as possible to the inner and outer edges 124I, 124O of the annular groove 124. For example, a distance between the inner edge 124I of the annular groove 124 and the neighboring vacuum suction groove 628 may be equal to or less than 4 mm or 3 mm or 2 mm or 1 mm. The same positional relationship may hold for the distance between the outer edge 124O of the annular groove 124 and the neighboring vacuum suction groove 628. The vacuum suction grooves 628 may be circular and concentric with the annular groove 124.

FIG. 7 illustrates an example of a wafer support plate 122. The wafer support plate 122 may include radial vacuum suction grooves 728. The radial vacuum suction grooves 728 may connect the circular vacuum suction grooves 628. The radial vacuum suction grooves 728 are not connected to the annular groove 124.

The wafer support plate 122 may, e.g., be used for a wafer chuck 120 for supporting 6 inch wafers. A 6 inch wafer may have a diameter in a range between 149.75 mm and 150.25 mm. The wafer support plate 122 may have a diameter of 220 mm and/or a thickness of 10 mm. The groove width WG may, e.g., be 6±0.02 mm. The groove depth may, e.g., be 2 mm. The diameter of the inner edge 124I of the annular groove 124 may, e.g., be 148±0.1 mm. The wafer support plate 122 may include a plurality of ventilation channels 126, in this example 6. The wafer support plate 122 is made of quartz glass, for example. All these features and dimensions of the specific example shown in FIG. 7 may be used selectively for any of the examples disclosed herein.

The inner edge 124I and/or the outer edge 124O of the annular groove 124 may have a linear section 124L. In this case, the linear sections 124L are shaped similar or in accordance (e.g. congruent) with the wafer edge 142 which, in some cases, is also equipped with a linear section. For example, the linear length of the wafer edge 142 of a 6 inch wafer 140 may, e.g., be in a range between 46 and 49 mm.

Other suitable wafer sizes which may be supported by the wafer support plate 122 of the wafer chuck 120 are 6 inch wafers, 8 inch wafers, 12 inch wafers and wafers greater than 12 inch.

The annular groove 124 may have a constant width along its entire circular extension, and e.g. also between the linear sections 124L of the annular groove edges 124I, 124O.

Referring to FIG. 8, a process of dicing a wafer may comprise at S1 placing the wafer on an upper surface of a wafer support plate of a chuck, wherein a dicing tape is disposed between the upper surface and the wafer. The upper surface comprises an annular groove that overlaps the wafer edge. The annular groove allows to avoid contact between the upper surface of the wafer support plate and the dicing tape in a small region radially outward the wafer edge.

At S2 the annular groove is ventilated.

At S3 the wafer is cut into dies by passing a laser beam over the wafer. The energy of the laser beam has to be set in accordance with the parameters of laser dicing, including in particular the material of the wafer, the thickness of the wafer and (optionally) the thickness of the dicing tape. The dicing tape may, e.g., be relatively thin (compared to dicing tapes which otherwise would need to be used in order to avoid surface damage or surface contamination) and may have, e.g., a thickness equal to or less than 200 μm or 150 μm or 100 μm.

At S4 the dicing tape is lifted off the upper surface of the wafer support plate of the chuck. Lifting the dicing tape 160 may be accomplished by moving the dicing frame 170 away from the chuck 120 (see FIG. 1). As mentioned above, the lift-off procedure is greatly facilitated by the provision of the annular groove 124 in the wafer support plate 122.

The following examples pertain to further aspects of the disclosure:

Example 1 is a chuck for a laser beam wafer dicing equipment includes a wafer support plate having an upper surface for holding a wafer disposed on a dicing tape. The upper surface includes an annular groove that overlaps the wafer edge when the wafer disposed on the dicing tape is placed on the upper surface. The wafer support plate includes a ventilation channel configured to ventilate the annular groove.

In Example 2, the subject matter of Example 1 can optionally include wherein the entire wafer edge projects radially beyond an inner edge of the annular groove.

In Example 3, the subject matter of Example 1 or 2 can optionally include wherein the annular groove has a width between 1 and 8 mm, in particular between 5 and 7 mm.

In Example 4, the subject matter of any preceding Example can optionally include wherein the annular groove has a depth equal to or greater than 0.1 mm.

In Example 5, the subject matter of any preceding Example can optionally include wherein the wafer support plate comprises a vacuum system configured to hold the dicing tape to the upper surface by suction.

In Example 6, the subject matter of Example 5 can optionally include wherein the vacuum system comprises vacuum suction grooves and/or vacuum suction holes formed in the upper surface, wherein the vacuum suction grooves and/or vacuum suction holes are provided radially inside and radially outside the annular groove.

In Example 7, the subject matter of Example 5 or 6 can optionally further include a base plate arranged below and spaced apart from the wafer support plate; and an annular sealing disposed between the base plate and the wafer support plate, the annular sealing defining an inner vacuum region and an outer vented region between the base plate and the wafer support plate.

In Example 8, the subject matter of Example 7 can optionally include wherein the vacuum system of the wafer support plate is in communication with the inner vacuum region, and the ventilation channel of the wafer support plate is in communication with the outer vented region.

In Example 9, the subject matter of any of the preceding Examples can optionally include wherein the wafer support plate is of quartz glass.

Example 10 is a laser beam wafer dicing equipment comprising a chuck according to any of the preceding Examples and a laser unit for producing a laser beam configured to cut the wafer into dies when passed over the wafer.

In Example 11, the subject matter of Example 10 can optionally include wherein the laser unit comprises a pulse laser.

In Example 12, the subject matter of Example 10 or 11 can optionally include wherein the laser unit comprises a UV laser or a green laser or an IR laser.

Example 13 is a method of dicing a wafer, the method comprising: placing a wafer on an upper surface of a wafer support plate of a chuck, wherein a dicing tape is disposed between the upper surface and the wafer, and the upper surface comprises an annular groove that overlaps the wafer edge; ventilating the annular groove; cutting the wafer into dies by passing a laser beam over the wafer; and lifting the dicing tape together with the dies off the upper surface.

In Example 14, the subject matter of Example 13 can optionally further include applying a wafer edge overcut when cutting the wafer into dies, wherein the wafer edge overcut length depends on the size of the dies to be produced, and wherein an outer edge of the annular groove extends radially beyond the wafer edge by at least the maximum overcut length.

In Example 15, the subject matter of Example 13 or 14 can optionally include wherein the wafer is a SiC wafer.

In Example 16, the subject matter of any of Examples 13 to 15 can optionally include wherein the wafer has a thickness of equal to or greater than 100 μm.

What is claimed is:

1. A chuck for a laser beam wafer dicing equipment, the chuck comprising:
a wafer support plate having an upper surface for holding a wafer disposed on a dicing tape,
wherein the upper surface comprises an annular groove that overlaps an edge of the wafer when the wafer disposed on the dicing tape is placed on the upper surface,
wherein the wafer support plate comprises a ventilation channel configured to ventilate the annular groove.

2. The chuck of claim 1, wherein the entire wafer edge projects radially beyond an inner edge of the annular groove.

3. The chuck of claim 1, wherein the annular groove has a width between 1 and 8 mm.

4. The chuck of claim 1, wherein the annular groove has a depth equal to or greater than 0.1 mm.

5. The chuck of claim 1, wherein the wafer support plate comprises a vacuum system configured to hold the dicing tape to the upper surface by suction.

6. The chuck of claim 5, wherein the vacuum system comprises vacuum suction grooves and/or vacuum suction holes formed in the upper surface, wherein the vacuum suction grooves and/or vacuum suction holes are provided radially inside and radially outside the annular groove.

7. The chuck of claim 5, further comprising:
a base plate arranged below and spaced apart from the wafer support plate; and
an annular sealing disposed between the base plate and the wafer support plate, the annular sealing defining an inner vacuum region and an outer vented region between the base plate and the wafer support plate.

8. The chuck of claim 7, wherein the vacuum system of the wafer support plate is in communication with the inner vacuum region, and wherein the ventilation channel of the wafer support plate is in communication with the outer vented region.

9. The chuck of claim 1, wherein the wafer support plate comprises quartz glass.

10. A laser beam wafer dicing equipment, comprising:
the chuck of claim 1; and
a laser unit configured to produce a laser beam configured to cut the wafer into dies when passed over the wafer.

11. The laser beam wafer dicing equipment of claim 10, wherein the laser unit comprises a pulse laser.

12. The laser beam wafer dicing equipment of claim 10, wherein the laser unit comprises a UV laser or a green laser or an IR laser.

13. A method of dicing a wafer, the method comprising:
placing a wafer on an upper surface of a wafer support plate of a chuck, wherein a dicing tape is disposed between the upper surface and the wafer and the upper surface comprises an annular groove that overlaps an edge of the wafer;
ventilating the annular groove;
cutting the wafer into dies by passing a laser beam over the wafer; and
lifting the dicing tape together with the dies off the upper surface.

14. The method of claim 13, further comprising:
applying a wafer edge overcut when cutting the wafer into dies, wherein a length of the wafer edge overcut depends on the size of the dies to be produced, and wherein an outer edge of the annular groove extends radially beyond the wafer edge by at least the maximum overcut length.

15. The method of claim 13, wherein the wafer is a SiC wafer.

16. The method of claim 13, wherein the wafer has a thickness of equal to or greater than 100 μm.
